(19) United States
(12) Patent Application Publication
(10) Pub. No.: US 2009/0103430 A1
(43) Pub. Date: Apr. 23, 2009

(54) SYSTEM AND METHOD OF MANAGING FAILOVER NETWORK TRAFFIC

(75) Inventor: Lei Wang, Austin, TX (US)

Correspondence Address: LARSON NEWMAN ABEL & POLANSKY, LLP, 5914 WEST COURTYARD DRIVE, SUITE 200, AUSTIN, TX, 78730, US

(73) Assignee: DELL PRODUCTS, LP, Round Rock, TX (US)

(21) Appl. No.: 11/874,301

(22) Filed: Oct. 18, 2007

(51) Int. Cl. G06F 11/00; G01R 31/08

(52) U.S. Cl. 370/221

(57) ABSTRACT

A system and method of managing failover network traffic is disclosed. In one form, a method of managing network traffic can include accessing a failover policy of a plurality of network interface controllers, and detecting a failover event of at least one of the plurality of network interface controllers. The method can also include identifying a first network traffic using the failover policy, and enabling communication of the first network traffic using a non-failed network interface controller of the plurality of network interface controllers.

### FIELD OF THE DISCLOSURE

This disclosure relates generally to information handling systems, and more particularly to a system and method of managing failover network traffic.

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements can vary between different applications, information handling systems can also vary regarding what information is handled, how the information is handled, how much information is processed, stored, or communicated, and how quickly and efficiently the information can be processed, stored, or communicated. The variations in information handling systems allow for information handling systems to be general or configured for a specific user or specific use such as financial transaction processing, airline reservations, enterprise data storage, or global communications. In addition, information handling systems can include a variety of hardware and software components that can be configured to process, store, and communicate information and can include one or more computer systems, data storage systems, and networking systems.

In some information handling systems, fault tolerance teaming modes can provide network connection redundancy by designating a primary Network Interface Card (NIC) and utilizing a secondary NIC as backup. For example, when the primary NIC loses link (e.g., is inoperable), the teaming driver of a system's network interface will fail over the traffic to the secondary or backup NIC. In some conventional systems, mixed speed fault tolerance teaming can be used to allow NICs of different speeds to be teamed together. For example, existing teaming modes like Adapter Fault Tolerance (AFT), Switch Fault Tolerance (SFT), and 802.3 ad dynamic modes, support mixed speed settings among team members.

However, such solutions to date can be inefficient in certain network or system communication topologies. For example, a primary 10 GE (Gigabit-Ethernet) NIC is carrying 16 Gbps (Gigabits-per-second) of traffic, and a 1 GE backup NIC can only carry as much as 1.8 Gbps traffic. Due to the speed difference, the 1 GE backup NIC can only take up a fraction of the 10 GE NIC traffic to protect. As such, the 1 GE NIC will pick up traffic to protect on a random basis.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 illustrates a block diagram of an information handling system according to one aspect of the disclosure;

FIG. 2 illustrates a functional block diagram of a network traffic monitor and control system according to another aspect of the disclosure;

FIG. 3 illustrates a flow diagram of a method updating and maintaining failover policy information according to a one aspect of the disclosure; and

FIG. 4 illustrates a flow diagram of a method of using failover policy information according to a one aspect of the disclosure.

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other teachings can certainly be utilized in this application. The teachings can also be utilized in other applications and with several different types of architectures such as distributed computing architectures, client/server architectures, or middleware server architectures and associated components.

For purposes of this disclosure, an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system can be a personal computer, a PDA, a consumer electronic device, a wireless communication device, a diskless computer system, a thin client, a network server or storage device, a switch router, wireless router, or other network communication device, or any other suitable device and can vary in size, shape, performance, functionality, and price. The information handling system can include memory, one or more processing resources such as a central processing unit (CPU) or hardware or software control logic. Additional components of the information handling system can include one or more storage devices, one or more communications ports for communicating with external devices as well as various input and output (I/O) devices, such as a keyboard, a mouse, and a video display. The information handling system can also include one or more buses operable to transmit communications between the various hardware components.

According to one aspect of the disclosure, a method of managing network traffic is disclosed. The method can include accessing a failover policy of a plurality of network interface controllers, and detecting a failover event of at least one of the plurality of network interface controllers. The method can also include identifying a first network traffic using the failover policy, and enabling communication of the first network traffic using a non-failed network interface controller of the plurality of network interface controllers.

According to another aspect of the disclosure, a failover management system is disclosed. The failover management system can include a failover control module coupled to a plurality of network interface controllers, and a traffic analyzer configured to determine a first network traffic pattern. The failover management system can also include a failover policy accessible to the failover control module to enable communication of the first network traffic pattern in response to a failover event being detected.

According to a further aspect of the disclosure, an information handling system is disclosed. The information handling system can include a plurality of network interface controllers operable to communicate information using a network, and a traffic detection and control module operably coupled to the plurality of network interface controllers. The traffic detection and control module can include a failover control module operable to enable communication using at least one of the plurality of network interface controllers, and a traffic analyzer module operable to analyze network traffic to detect a failover network traffic. The traffic detection and control module can also include a failover policy configured to enable communication of the failover network traffic using a failover network communication interface.

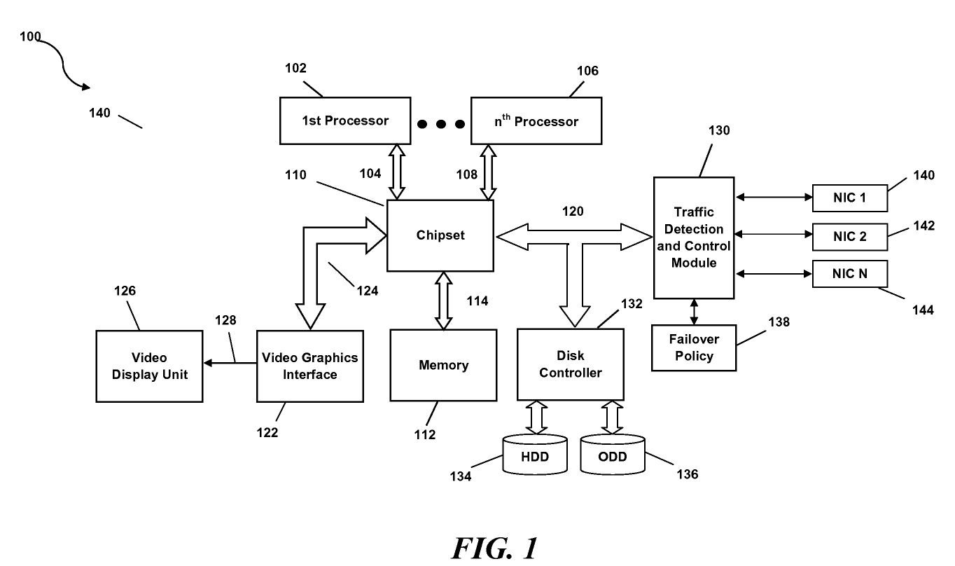

FIG. 1 illustrates a block diagram of an exemplary embodiment of an information handling system, generally designated at 100. In one form, the information handling system 100 can be a computer system such as a server. As shown in FIG. 1, the information handling system 100 can include a first physical processor 102 coupled to a first host bus 104 and can further include additional processors generally designated as physical processor 106 coupled to a second host bus 108. The first physical processor 102 can be coupled to a chipset 110 via the first host bus 104. Further, the n^{th} physical processor 106 can be coupled to the chipset 110 via the second host bus 108. The chipset 110 can support multiple processors and can allow for simultaneous processing of multiple processors and support the exchange of information within information handling system 100 during multiple processing operations.

According to one aspect, the chipset 110 can be referred to as a memory hub or a memory controller. For example, the chipset 110 can include a dedicated bus to transfer data between first physical processor 102 and the n^{th} physical processor 106. For example, the chipset 110 including a chipset that can include a memory controller hub and an input/output (I/O) controller hub. As a memory controller hub, the chipset 110 can function to access the first physical processor 102 using first bus 104 and the n^{th} physical processor 106 using the second host bus 108. The chipset 110 can also be used as a memory interface for accessing memory 112 using a memory bus 114. In a particular embodiment, the buses 104, 108, and 114 can be individual buses or part of the same bus. The chipset 110 can also include bus control and can handle transfers between the buses 104, 108, and 114.

According to another aspect, the chipset 110 can include an application specific chipset that connects to various buses, and integrates other system functions. For example, the chipset 110 can include using an Intel® Hub Architecture (IHA) chipset that can also include two parts, a Graphics and AGP Memory Controller Hub (GMCH) and an I/O Controller Hub (ICH). For example, an Intel 820E, an 815E chipset, an Intel 975X chipset, an Intel G965 chipset, available from the Intel Corporation of Santa Clara, Calif., or any combination thereof, can be used as at least a portion of the chipset 110. The chipset 110 can also be packaged as an application specific integrated circuit (ASIC).

In one form, the chipset 110 can be coupled to a video graphics interface 122 using a third bus 124. In one form, the video graphics interface 122 can be a Peripheral Component Interconnect (PCI) Express interface operable to content to display within a video display unit 126. Other graphics interfaces may also be used. The video graphics interface 122 can output a video display output 128 to the video display unit 126. The video display unit 126 can include one or more types of video displays such as a flat panel display (FPD), cathode ray tube display (CRT) or other type of display device.

The information handling system 100 can also include an I/O interface 130 that can be connected via an I/O bus 120 to the chipset 110. The I/O interface 130 and I/O bus 120 can include industry standard buses or proprietary buses and respective interfaces or controllers. For example, the I/O bus 120 can also include a PCI bus or a high speed PCI-Express bus. In one embodiment, a PCI bus can be operated at approximately 66 MHz and a PCI-Express bus can be operated at more than one (1) speed (e.g. 2.5 GHz and 5 GHz). PCI buses and PCI-Express buses can comply with industry standards for connecting and communicating between various PCI-enabled hardware devices. Other buses can also be used in association with, or independent of, the I/O bus 120 including, but not limited to, industry standard buses or proprietary buses, such as Industry Standard Architecture (ISA), Small Computer System Interface (SCSI), Inter-Integrated Circuit (I²C), System Packet Interface (SPI), or Universal Serial buses (USBs).

In an alternate embodiment, the chipset 110 can be a chipset employing a Northbridge/Southbridge chipset configuration (not illustrated). For example, a Northbridge portion of the chipset 110 can communicate with the first physical processor 102 and can control interaction with the memory 112, the I/O bus 120 that can be operable as a PCI bus, and activities for the video graphics interface 122. The Northbridge portion can also communicate with the first physical processor 102 using first bus 104 and the second bus 108 coupled to the n^{th} physical processor 106. The chipset 110 can also include a Southbridge portion (not illustrated) of the chipset 110 and can handle I/O functions of the chipset 110. The Southbridge portion can manage the basic forms of I/O such as Universal Serial Bus (USB), serial I/O, audio outputs, Integrated Drive Electronics (IDE), and ISA I/O for the information handling system 100.

The information handling system 100 can further include a disk controller 132 coupled to the I/O bus 120, and connecting one or more internal disk drives such as a hard disk drive (HDD) 134 and an optical disk drive (ODD) 136 such as a Read/Write Compact Disk (R/W CD), a Read/Write Digital Video Disk (R/W DVD), a Read/Write mini-Digital Video Disk (R/W mini-DVD), or other type of optical disk drive.

The information handling system 100 can also include a traffic detection and control module 130 operable to be coupled to one or more of a first NIC 140, a second NIC 142, and an n^{th} NIC 144. The traffic detection and control module 130 can further be coupled to the I/O bus 130 and a failover policy source 138. The failover policy source 138 can be stored within a memory of the traffic detection and control module 130 or within a memory or storage device of the information handling system 100 that can be accessed by the traffic and control module 130. In one form, the first NIC 140 can be configured to be a 10 GE network interface card. Additionally, the second NIC 142, the n^{th} NIC 144, or any combination thereof, can be configured as a network interface card that operates at one or more speeds less than 10 GE (e.g. a 1 GE NIC).

During operation, the traffic detection and control module 130 can access a failover policy 138 that can include one or more entries to route traffic to one or more of the first NIC, second NIC, n^{th} NIC, in the event one or more fails or a communication link is lost. For example, the failover policy 138 can be updated based on network traffic detected by the traffic detection and control module 130. In one form, network traffic can be prioritized by sampling data packet header information. For example, the traffic detection and control module 130 can access protocol fields within the IP header of data packets within the network traffic, and the destination of the data packets. In other forms, a port number, such as “3260” within the Transmission Control Protocol (TCP) header can be identified. Additionally, an Internet SCSI (iSCSI) boot traffic can be identified and labeled as high priority for failover support. Various other forms of identifying data packets can also be used as desired.

According to one aspect, the failover policy 138 can then store one or more references to failover priority data that can be used to route specific data or network traffic over one or more functioning NICs in the event one or more of the system NICs fail. In this manner, critical or network traffic having a higher priority can be communicated. For example, a system administrator may desire to access one or more portions of the information handling system 100 when a NIC fails or becomes inoperable. As such, network traffic of the system administrator can be communicated based on a priority level established and not lost. Additionally, network traffic, connection attempts, etc. that may be lower priority, or non-critical, can be ignored or rejected. In this manner, bandwidth to be used by higher priority or critical traffic can be preserved.

In another form, a user of the information handling system 100 can establish a priority level to a specific type of traffic to protect to ensure that the specific type of traffic can be communicated. For example, the information handling system 100 can communicate network traffic in association with an iSCSI boot or other initialization routine or source. As such, failover policy 138 can include a reference to the iSCSI boot traffic that can be identified as having a high priority to the iSCSI boot traffic.

In another form, one or more of the NICs can be provided as network communication modules attached to a system board of the information 100, and can be used to output a local area network on motherboard (LOM). For example, one or more of the NICs can be realized as a LOM-enabled network communication device. As such, the LOM-enabled network communication device can fail and the traffic detection and control module 130 can determine a failover policy 138 of the LOM, and route traffic between an enabled LOM based o the failover policy 130. In another form, the traffic detection and control module 130 can be realized as a part of the network fabric, or in other forms can be realized as software or other logic that can be processed the first processor 102, n^{th} processor 106, or various other devices, processors, etc. of the information handling system 100 capable of determining a failover policy 138 to ensure network traffic having a desired priority can be communicated in the event of communication failure.

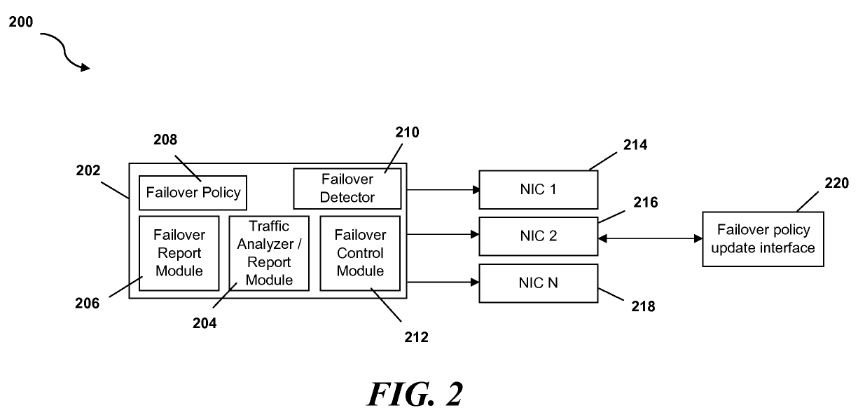

FIG. 2 illustrates a functional block diagram of a failover management system, illustrated generally at 200, that can include a network traffic detection and control module 202, a network traffic analyzer and report module 204, a failover report module 206, a failover policy 208, a fault detector 210, and a failover control module 212. The network traffic and control module 202 can be coupled to a first NIC 214, a second NIC 216, and n^{th} NIC 218. The failover management system 200 can further include a failover policy update interface 220 that can access the network traffic detection and control module 202 to update and set the failover policy 208. The failover policy update interface 220 can be used in association with management control interface, network administrator application or interface, a custom application made available to a customer, or any other type of user interface that can allow access to the failover policy 208. In one form, a user can create a failover policy from a remote system and update multiple systems including a failover policy source. In this manner, specific types of policies can be established to ensure that specific types of network traffic can be prioritized. Additionally, users that may have numerous information handling systems can provide a global policy via a single point without having to access each information handling system on an individual basis.

In one form, during operation the traffic analyzer and report module 204 can sample network traffic of the first NIC 214, the second NIC 216 and the n^{th} NIC 218 to detect one or more repeated patterns within the network traffic. Upon detecting one or more patterns, the traffic analyzer and report module 204 can further monitor the network traffic over a period of time (e.g. 5 seconds, 30 seconds, 1 minute, 10 minutes, etc.) to detect a frequency of types of traffic communicated within the network traffic. The traffic analyzer and report module 204 can further analyze the network traffic and present different failover protection options based on a primary and alternative NIC capabilities of the first NIC, the second NIC, and the n^{th} NIC 218. As such, a user can select a failover option based on the network traffic and establish or set the failover policy 208. In this manner, when the fault detector 210 detects a failover event of one or more of the NICs, the failover control module 212 can access the failover policy 208 and apply the policy and rules specified within the failover policy 208 to automatically provide failover support and enable communication of specific network traffic detected in the failover policy 208. Additionally, the failover event and applied policy can be stored within the failover report module 206, and a user, application, etc. can access the failover report that identifies traffic that has been failed over. The failover report module 206 can further store alternative failover suggestions using the failover policy 208 to assist with a failback and recovery plan.

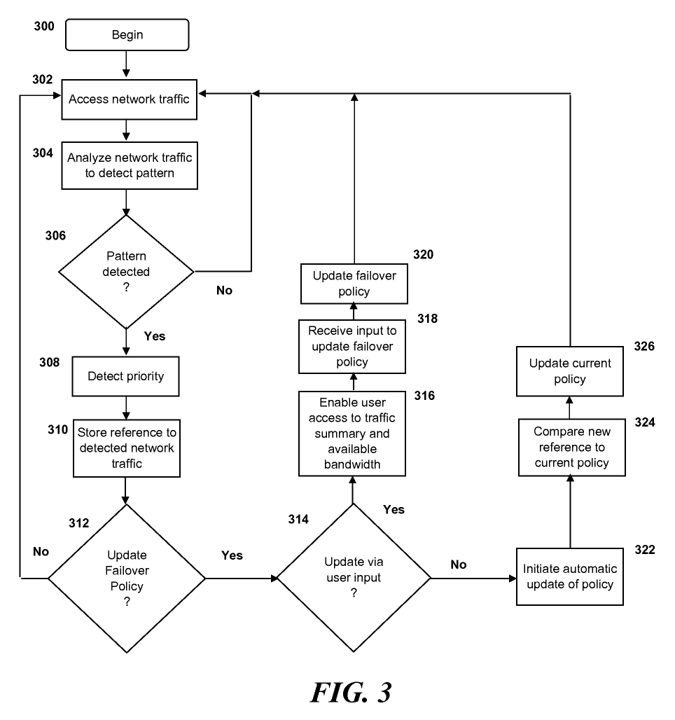

FIG. 3 illustrates a flow diagram of a method updating and maintaining failover policy information according to a one aspect of the disclosure. FIG. 3 can be employed in whole, or in part, by the information handling system 100 depicted in FIG. 1, the failover management system 200 described in FIG. 2, or any other type of system, controller, device, module, processor, or any combination thereof, operable to employ all, or portions of, the method of FIG. 3. Additionally, the method can be embodied in various types of encoded logic including software, firmware, hardware, or other forms of digital storage mediums, computer readable mediums, or logic, or any combination thereof, operable to provide all, or portions, of the method of FIG. 3.

The method begins generally at block 300. At block 302, network traffic received by one or more NICs coupled to a traffic detection and control module can be accessed. In one form, the traffic detection and control module can be provided as a part of a network teaming device, load balancer, network hub, LOM controller, or any other communication device that can access receive network traffic. Upon access the network traffic, the method can proceed to block 304 and analyzes network traffic to detect a pattern within the network traffic. For example, network traffic can include multiples of data packets originating from a single source, or in association with a single process. If at decision block 306 a pattern cannot be detected, the method can proceed to block 302 and repeats. If at decision block 306, a pattern can be detected, the method can proceed to block 308 and detects a priority to associate with the detected pattern. For example, the type of data can be identified using a look up table, priority list, or other source and compared to detect a priority of the detected network traffic. For example, network traffic headers, including, but not limited to, Ethernet, IP, and TCP/UDP headers, the destination and source IP addresses, protocol type, TCP, user datagram protocol (UDP) source and destination port numbers could be examined. The data can be compared to against predefined values, priorities, categories, or any combination thereof to detect a priority of the network traffic.

Upon detecting a priority, the method can proceed to block 310 and a reference to the type of data and a suggested priority can be stored and used to determine a failover policy. The method can then proceed to decision block 312 and determines if the failover policy should be updated. For example, the type of data detected within the network traffic can include data having a higher priority. As such, if at decision block 312, the failover policy need not be updated, the method can proceed to block 302 and repeat. If at decision block 312, the failover policy should be updated, the method can proceed to decision block 314 and determines if the failover policy should be updated via a user input or automatically. If at decision block 314 a user can update the failover policy, the method can proceed to block 316 and a user can access traffic summary data and available bandwidth of one or more NICs. In one embodiment, the method can be modified to output a suggested failover policy, and a user can select the suggested policy, or modify the policy as desired. In this manner, a user can determine a type of network traffic to communicate in the event a failover situation occurs to ensure specified data can be communicated using available resources. As such, at block 318, when an input to update the failover policy can be received, and the method can proceed to block 320 ad updates the failover policy of the information handling system. The method can then proceed to block 302 and repeats.

If at decision block 314, the failover policy should be updated automatically, the method can proceed to block 322 and an automatic updated of the failover policy can be initiated. The method can also proceed to block 324, and one or more references, priorities, type of data detected, etc. can be compared to the current policy to determine if data detected should have a higher priority in the event of failover. The method can then proceed to block 326 and updates the current policy as desired. The method can then proceed to block 302 and repeats.

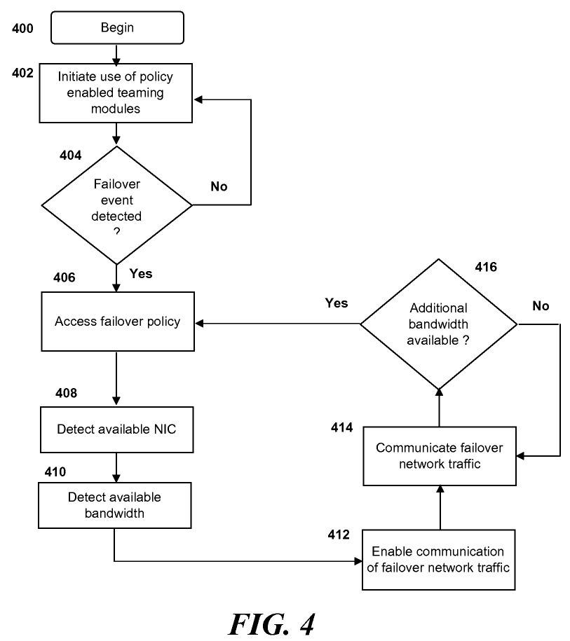

FIG. 4 illustrates a flow diagram of a method enabling failover protection according to a one aspect of the disclosure. FIG. 4 can be employed in whole, or in part, by the information handling system 100 depicted in FIG. 1, the failover management system 200 described in FIG. 2, or any other type of system, controller, device, module, processor, or any combination thereof, operable to employ all, or portions of, the method of FIG. 4. Additionally, the method can be embodied in various types of encoded logic including software, firmware, hardware, or other forms of digital storage mediums, computer readable mediums, or logic, or any combination thereof, operable to provide all, or portions, of the method of FIG. 4.

The method begins generally at block 400. At block 402, network teaming of multiple NICs can be enabled using a failover policy as described above. Upon employing a failover policy, the method can proceed to decision block 404 and determines if a failover event may be detected. If a failover event can not be detected, the method can proceed to block 402 and repeats. If at decision block 404, a failover event can be detected, the method proceeds to block 406 and accesses a failover policy. For example, the failover policy as described above can include references to one or more types of network traffic to enable. Additionally, the failover policy can also determine one or more NICs to enable a specific traffic to be communicated. Upon determining the failover policy, the method can proceed to block 408 and detects if a NIC may be available to communicate the network traffic. Upon determining an available NIC, the method can proceed to block 410 and detects bandwidth available at the NIC or combinations of NICs. For example, high priority network traffic can be communicated using one or more NICs. Upon determining bandwidth availability, the method can proceed to block 412 and enables communication of the failover network traffic using the available NIC and bandwidth. The method can then proceed to block 414 and communicates the failover network traffic. The method can then proceed to decision block 416 and determines if additional bandwidth may be available. If no additional bandwidth may be available, the method can proceed to block 414 and continues. In one form, the method can be modified to detect whether the failover event has been fixed.

If at decision block 416, additional bandwidth may be available, the method can proceed to block 406 and can access the failover policy to determine additional network traffic to communicate. For example, network traffic having a lower priority can be communicated using the available bandwidth. In one form, network traffic having a first priority can be communicated using a first portion of a bandwidth of a failover NIC. Additionally, network traffic having a second priority can be coupled to the failover NIC if additional bandwidth may be available. In this manner, more than one prioritized network traffic can be coupled to a failover NIC during failover operation and traffic that may not be critical may be filtered based on a failover policy of information handling system.

Although only a few exemplary embodiments have been described in detail above, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A method of managing network traffic, the method comprising:
accessing a failover policy of a plurality of network interface controllers;
detecting a failover event of at least one of the plurality of network interface controllers using a failover control module coupled to the plurality of network interface controllers;
identifying a first network traffic using the failover policy; and
enabling communication of the first network traffic using a non-failed network interface controller of the plurality of network interface controllers.

2. The method of claim 1, further comprising:
identifying a second network traffic using the failover policy;
determining an available communication bandwidth of the non-failed network interface controller; and
enabling communication of the second network traffic using the available communication bandwidth of the non-failed network interface controller.

3. The method of claim 1, further comprising:
identifying a second network traffic using the failover policy;
determining a non-available communication bandwidth of the non-failed network interface controller; and
disabling communication of the second network traffic using the non-failed network interface controller.

4. The method of claim 1, further comprising
accessing a teamed network traffic in a teamed network communication environment;
detecting a first pattern within the teamed network traffic;
detecting a first priority of the first pattern; and
updating the failover policy of using the first priority of the first pattern.

5. The method of claim 4, further comprising:
adding a first reference to the failover policy to identify the first network pattern within the teamed network traffic;
adding a first priority reference to the failover policy;
adding a second reference to the failover policy to identify a second network pattern within the teamed network traffic; and
adding a second priority reference to the failover policy.

6. The method of claim 1, further comprising:
enabling a user access to a traffic summary;
enabling a user access to an available bandwidth reference of the non-failed network interface controller;
receiving a first input by the user to enable communication of the first network traffic when the failover event is detected;
receiving an second input by the user to enable communication of the first network traffic using the available bandwidth reference; and
updating the failover policy to include the first input and the second input.

7. The method of claim 1, further comprising:
initiating an automated updating of the failover policy in response to detecting the first network traffic pattern;
comparing the failover policy to a new reference; and
updating the failover policy in response to the comparison.

8. The method of claim 1, further comprising:
identifying a failover network interface controller within the plurality of network interface controllers;
detecting an available bandwidth of a failover network interface controller;
detecting a network traffic type communicated using the plurality of network interface controllers;
determining a failover suggestion based on the available bandwidth and network traffic type;
detecting a selection of the failover suggestion; and
enabling use of the selection in response to the failover being detected.

9. The method of claim 1, further comprising:
storing a failover report within a failover report module;
updating the failover report to include a failover event reference;
updating the failover report to include a failback suggestion in response to detecting the failover event; and
enabling a user access to the failover report.

10. A failover management system comprising:
a failover control module coupled to a plurality of network interface controllers;
a network traffic analyzer configured to identify a first network traffic pattern within a network traffic; and
a failover policy accessible to the failover control module to enable communication of the first network traffic pattern in response to a failover event being detected.

11. The failover management system of claim 10, further comprising a failover detector coupled to the failover control module, the failover detector operable to detect failure of at least one of the plurality of network interface controllers.

12. The failover management system of claim 10, comprising:
wherein the network traffic analyzer is further configured to access the network traffic to detect the first network traffic pattern and a second network traffic pattern; and
a report module coupled to the network traffic analyzer, the report module configured to store a first reference to the first network traffic pattern and a second reference to the second network traffic pattern.

13. The failover management system of claim 10, further comprising a failover report configured to store failover information of a detected failover event.

14. The failover management system of claim 10, further comprising a user interface configured to:
output a current failover policy;
output a first reference to the first network traffic pattern;
output a second reference to a second network traffic pattern;
output a suggested failover policy; and
receive a user selected updated failover policy.

15. The failover management system of claim 14, further comprising the user interface configured to couple the updated failover policy to the failover controller.

16. The failover management system of claim 10, further comprising a teamed network communication environment configured to be responsive to the failover policy.

17. An information handling system comprising:
a plurality of network interface controllers operable to communicate information using a network; and
a traffic detection and control module operably coupled to the plurality of network interface controllers, the traffic detection and control module including:
a failover control module operable to enable communication using at least one of the plurality of network interface controllers;
a traffic analyzer module operable to analyze network traffic to detect a failover network traffic; and
a failover policy configured to enable communication of the failover network traffic using a failover network communication interface.

18. The information handling system of claim 17, further comprising the failover detection module operable to detect a failover event.

19. The information handling system of claim 18, further comprising a teamed network operating environment responsive to the failover detection module and the failover policy.

20. The information handling system of claim 18, further comprising a remote access user interface operable to enable a user to the update the failover policy using network traffic information and bandwidth availability detected by the traffic detection and controller module.
